(19) United States
(12) Patent Application Publication
(10) Pub. No.: US 2023/0129986 A1
(43) Pub. Date: Apr. 27, 2023

(54) QUANTIFYING UNCERTAINTY IN POROSITY COMPACTION MODELS OF SEDIMENTARY ROCK

(71) Applicant: SAUDI ARABIAN OIL COMPANY, Dhahran (SA)

(72) Inventor: Wisam AlKawai, Qatif (SA)

(73) Assignee: SAUDI ARABIAN OIL COMPANY, Dhahran (SA)

(21) Appl. No.: 17/452,280

(22) Filed: Oct. 26, 2021

(51) Int. Cl. G01V 99/00; G06F 30/20; G06F 17/18; E21B 49/02

(52) U.S. Cl. CPC G01V 99/005; G06F 30/20; G06F 17/18; E21B 49/02; E21B 2200/20

(57) ABSTRACT

Methods and systems for quantifying an uncertainty in at least one porosity compaction model parameter are disclosed. The method includes obtaining a first sequence of depth-porosity duplets from a sedimentary layer and generating a plurality of alternate sequences of depth-porosity duplets based, at least in part, on resampling the first sequence. The method further includes estimating a plurality of values for the porosity compaction model parameter based on fitting a porosity compaction model to the first sequence and each alternate sequence. The method further includes quantifying the uncertainty in the porosity compaction model parameter based on determining the value of a parameter of probability density function fit to a histogram of the plurality of values for the porosity compaction model parameter.

### BACKGROUND

Sedimentary basin models may be useful to the oil and gas industry as they can be used to predict the location, type, and volume of hydrocarbon resources over geological time. Sedimentary basin models make such predictions using embedded empirical models. Empirical models may estimate sedimentary layer facies—such as rock type, rock porosity, and fossil content—, sedimentary migration, and other geological processes. However, uncertainties lie in sedimentary basin model predictions due to uncertainties in the embedded empirical models. Of particular interest may be uncertainties in porosity compaction models as rock porosity may, at least in part, drive hydrocarbon location, migration, and volume. Quantifying uncertainties in porosity compaction models may lead to increased confidence in sedimentary basin model predictions and, ultimately, increased confidence that the predicted hydrocarbon resources will be prolific once accessed.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method of quantifying an uncertainty in at least one porosity compaction model parameter. The method includes obtaining a first sequence of depth-porosity duplets from a sedimentary layer and generating a plurality of alternate sequences of depth-porosity duplets based, at least in part, on resampling the first sequence. The method further includes estimating a plurality of values for the porosity compaction model parameter based on fitting a porosity compaction model to the first sequence and each alternate sequence. The method further includes quantifying the uncertainty in the porosity compaction model parameter based on determining the value of a parameter of probability density function fit to a histogram of the plurality of values for the porosity compaction model parameter.

In general, in one aspect, embodiments relate to a non-transitory computer readable medium storing instructions executable by a computer processor. The instructions include functionality for receiving a first sequence of depth-porosity duplets from a sedimentary layer and generating a plurality of alternate sequences of depth-porosity duplets based, at least in part, on resampling the first sequence. The instructions further include estimating a plurality of values for a porosity compaction model parameter based on fitting a porosity compaction model to the first sequence and each alternate sequence. The instructions still further include quantifying an uncertainty in the porosity compaction model parameter based on determining the value of a parameter of probability density function fit to a histogram of the plurality of values for the porosity compaction model parameter.

In general, in one aspect, embodiments relate to a system including a well tool configured to sample porosity at a plurality of depths and a computer system configured to receive a first sequence of depth-porosity duplets from a sedimentary layer collected using the well tool. The computer system is further configured to generate a plurality of alternate sequences of depth-porosity duplets based, at least in part, on resampling the first sequence. The computer system is further configured to estimate a plurality of values for a porosity compaction model parameter based on fitting a porosity compaction model to each sequence. The computer system is still further configured to quantify an uncertainty in the porosity compaction model parameter based on determining the value of a parameter of probability density function fit to a histogram of the plurality of values for the porosity compaction model parameter.

Other aspects and advantages of the claimed subject matter will be apparent from the following description and the appended claims.

### BRIEF DESCRIPTION OF DRAWINGS

Specific embodiments of the disclosed methodology will now be described in detail with reference to the accompanying figures. Like elements in the various figures are denoted by like reference numerals for consistency.

FIG. 1A depicts pores between rock grains with high porosity, in accordance with one or more embodiments.

FIG. 1B depicts pores between rock grains with low porosity, in accordance with one or more embodiments.

FIG. 2 shows a porosity compaction model, in accordance with one or more embodiments.

FIG. 3 shows a workflow, in accordance with one or more embodiments.

FIG. 4 shows a flowchart, in accordance with one or more embodiments.

FIG. 5 shows a flowchart, in accordance with one or more embodiments.

FIG. 6 illustrates a drill system, in accordance with one or more embodiments.

FIG. 7 depicts a computer system, in accordance with one or more embodiments.

### DETAILED DESCRIPTION

In the following detailed description of embodiments of the disclosure, numerous specific details are set forth to provide a more thorough understanding of the disclosure. However, it will be apparent to one of ordinary skill in the art that the disclosure may be practiced without these specific details. In other instances, well known features have not been described in detail to avoid unnecessarily complicating the description.

Throughout the application, ordinal numbers (e.g., first, second, third, etc.)

may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Modeling a sedimentary basin's history is imperative to predicting the presence, volume, and type of hydrocarbon resources that may be present in reservoirs within the sedimentary basin. Simulating the evolution of sediment porosity over geological time is one important element of basin modeling. Porosity uncertainty may be quantified using simple analytic forms, such as probability distributions. Such simple analytic forms allow uncertainties associated with porosity compaction models to be included in sedimentary basin models.

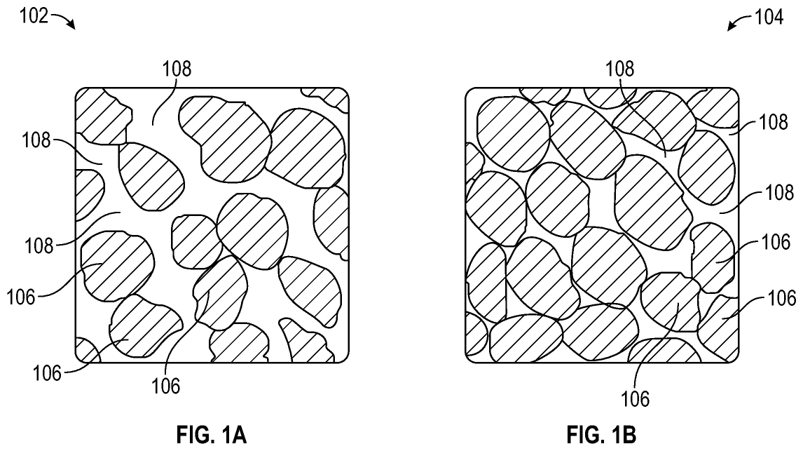

FIG. 1A depicts a cross-section through a rock sample (102) taken from a high porosity sedimentary layer in the Earth's crust. FIG. 1B depicts a cross-section through a rock sample (104) taken from a low porosity sedimentary layer. Referring to both FIGS. 1A and 1B, each rock sample contains a plurality of grains (106) composed of solids, that may be minerals or organic materials, and may vary in size from coarse sands to fine muds. Sediment with a significant proportion of organic material may include shale while course-grain sediments may include conglomerates and breccia and fine grain sediment may include mudstone. In addition to grains (106), each rock sample contains pores (108). Pores (108) are voids between the grains (106). Gas, such as natural gas or air, or liquids, such as oil, fresh water, or brine, may fill the pores (108). Porosity is defined as the fraction of the volume of a rock sample that is occupied by the pores (108). Further, porosity is a measure of how much gas or liquid a rock can hold. Sedimentary rocks typically have a porosity in the range of 0.1% to 40%.

Rock porosity is closely related to rock permeability. While porosity is a measure of how much fluid, i.e., gas or liquid, a rock can hold, permeability is a measure of how easily fluid can flow through the rock. The degree of connection between pores (108) constrains permeability. While a rock may have high porosity, if the degree of connection between pores (108) is low, permeability may also be low. However, in general, rocks with higher porosity tend to have higher permeability. The degree of connection between pores (108) and the permeability may vary both between rock samples of different porosity and between rock samples of the same porosity.

Over geological time, sedimentary layers may undergo mechanical, chemical, and/or biochemical changes that may result in porosity and permeability changes. Mechanical changes may occur due to weathering or erosion as well as sediment transportation. Alternatively, chemical changes may occur due to chemical weathering or erosion due to the dissolution and recombination of minerals. Further, biochemical sedimentation may occur due to organic lithification. As mechanical, chemical, and/or biochemical processes occur, overlying stratigraphic layers may also be added. Mechanical, chemical, and biochemical changes along with the weight of these overlying stratigraphic layers may cause underlying sedimentary layers to compact.

Compaction may result in tighter grain (106) packing and reduced grain size. Further, compaction may also result in pore (108) size reduction. Compaction over geological time and/or at varying depths may be quantified by the resulting change in porosity. Modeling the porosity of sedimentary layers, such as Cretaceous carbonate rock, over geological time and by depth of burial may provide insight into the location and volume of hydrocarbon resources entrapped in the pores (108) of sedimentary layers.

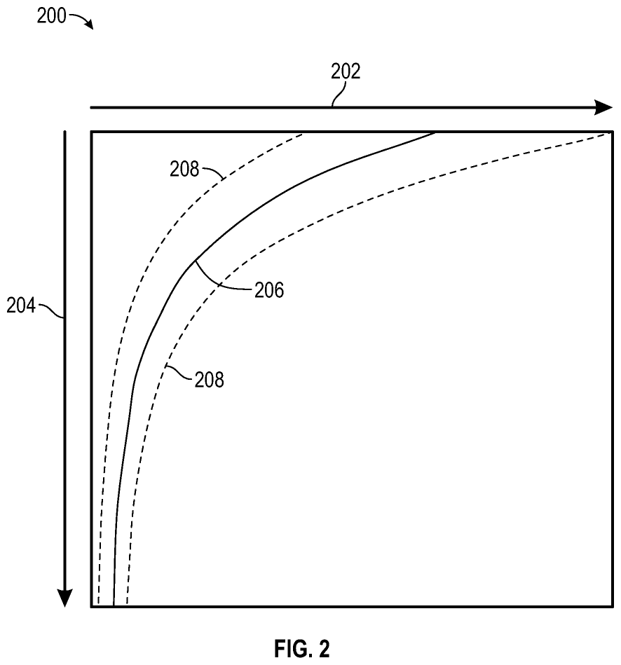

FIG. 2 shows a porosity compaction model (206), in accordance with one or more embodiments. The horizontal axis (202) represents porosity, increasing to the right, and the vertical axis (204) represents depth, increasing downward. The solid line (206) represents the average porosity as a function of depth with porosity decreasing with increasing depth. Further, the solid line (206) represents the average porosity for one sedimentary layer throughout the depth of the sediment. The dashed lines (208) represent the porosity compaction model uncertainty. In one embodiment, uncertainty may stem from the porosity compaction model being a poor fit to depth-porosity data.

Porosity compaction models (200) typically exhibit exponential decay given by:

φ(z)=φₘᵢₙ+(φ₀−φₘᵢₙ)e^{-cz} Equation (1)

where z is the depth below the surface, φₘᵢₙ is the minimum porosity, φ₀ is the archaic value of porosity of the sedimentary layer (i.e., the value of porosity at the time of deposition), and c is a compaction coefficient. Once c, φₘᵢₙ, and φ₀ are specified, equation (1) may predict the expected porosity, φ(z), that the sedimentary layer will have after burial to a depth, z. Conversely, if the value of porosity, φ(z), of a sedimentary layer is measured as a function of depth, z, using wellbore logs or by retrieving a plurality of rock core samples, the archaic value of porosity at the time of deposition may be estimated using:

φ₀=φₘᵢₙ+(φ(z)−φₘᵢₙ)e^{cz} Equation (2).

The minimum porosity, φₘᵢₙ, may be determined from wellbore logs, or core samples, or both. The compaction coefficient, c, and archaic porosity, φ₀, may be determined by fitting the porosity compaction model (200) to a sequence of sample depth, z, and porosity, φ(z), duplets. However, two modes of uncertainty may exist with this approach. First, uncertainty may exist in the depth-porosity duplets. Specifically, there may be error in the depth-porosity duplets (hereinafter also “z-φ(z) duplets”) due to data collection and measurement challenges particularly in porosity, φ(z). Further the measured porosity, φ(z), may not be representative of the average porosity of the stratigraphic layer at depths, z. Second, the porosity compaction model (200) may not be a reasonable approximation to the z-φ(z) duplets. Either, or both, forms of uncertainty may be manifested in the estimated compaction coefficient, c, and archaic porosity, φ₀.

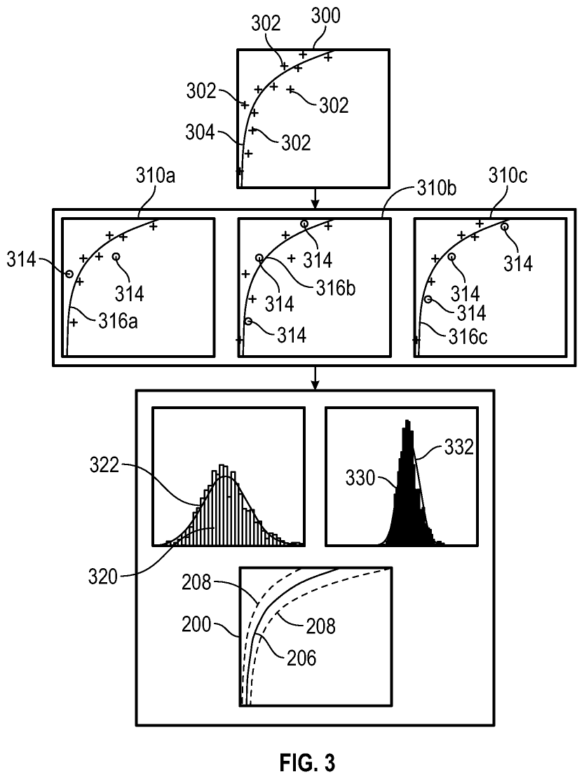

FIG. 3 depicts elements of a workflow for quantifying uncertainty in porosity compaction model parameters, in accordance with one or more embodiments. A first sequence of z-φ(z) duplets (300) is shown. Each z-φ(z) duplet (302) in the first sequence (300) may be obtained from a wellbore log or core samples. A porosity compact model (304) may be fit to the sequence of z-φ(z) duplets (300).

FIG. 3 also shows three alternate sequences of z-φ(z) duplets (310a, 310b, 310c) generated from the first sequence of z-φ(z) duplets (300) by resampling, in accordance with one or more embodiments. Resampling may be performed by any of a number of methods known to a person of ordinary skill in the art without departing from the scope of the invention. For example, resampling may be performed by a bootstrapping method, a jackknifing method, or a Monte Carlo method.

For example, a bootstrap method may be applied to the first sequence of z-φ(z) duplets (300). Bootstrapping draws random samples from the first sequence of z-φ(z) duplets (300). Resampling is performed until the same number of z-φ(z) duplets exist in each alternate sequence of z-φ(z) duplets (310a, 310b, 310c) as is in the first sequence of z-φ(z) duplets (300). Some z-φ(z) duplets (302) in the first sequence (300) may be selected multiple times (314) in each alternate sequence (310a, 310b, 310c), and other z-φ(z) duplets (302) in the first sequence (300) may not be selected in one or more alternate sequences (310a, 310b, 310c).

In other embodiments, a Monte Carlo sampling method may be performed by assuming the first sequence of z-φ(z) duplets (300) follows a probability distribution. The probability distribution may then be sampled to generate an alternate sequence of z-φ(z) duplets (310a, 310b, 310c). The Monte Carlo method may sample the assumed probability function an unlimited number of times to generate an unlimited number of alternate sequences (312a, 312b, 312c).

In accordance with one or more embodiments, a porosity compaction model (316a, 316b, 316c) may be fit to each alternate sequence z-φ(z) duplets (310a, 310b, 310c) to determine a compaction coefficient, c, and an archaic porosity value, φ₀. Although only three alternate sequences (312a, 312b, 312c) are shown in FIG. 3, a person of ordinary skill in the art will understand an unlimited number of alternate sequences (312a, 312b, 312c) may be generated by resampling, in accordance with one or more embodiments.

In accordance with one or more embodiments, a porosity compaction model (304) may be fit to the first sequence of z-φ(z) duplets (300) and a porosity compaction model (316a, 316b, 316c) may be fit to each alternate sequence of z-φ(z) duplets (310a, 310b, 310c). Fitting a porosity compaction model to the first sequence (300) and to each alternate sequence (310a, 310b, 310c) may determine a plurality of compaction coefficients, c, and a plurality of archaic porosities, φ₀. A histogram (320) of archaic porosity values, φ₀, may be determined and a probability density function (322) may be fit to the archaic porosity, φ₀, histogram (320). A histogram (330) of compaction coefficient values, c, may be determined and a probability density function (332) may be fit to the compaction coefficient, c histogram (330). The probability density functions (320, 330) may be, without limitation, a uniform distribution, a normal or Gaussian distribution, a skew distribution—such as the Rayleigh distribution—, an exponential distribution, a power-law distribution—such as the Pareto distribution—, a binomial distribution, and a Weibull distribution, with departing from the scope of the invention.

A common probability density function (322, 332) is a normal or Gaussian probability density function and may be expressed as:

$$f ( x ) = \frac{1}{σ \sqrt{2 π}} {e}^{- \frac{1}{2} {( \frac{x - μ}{σ} )}^{2}} \qquad Equation ( 3 )$$

where σ is the standard deviation and μ is the mean. The fitted probability density function (332) of the compaction coefficient, c, histogram (332) and fitted probability density function (322) of the archaic porosity, φ(0), histogram (320) may now be used to quantify porosity compaction model parameter uncertainty. Further, the porosity compaction model (200) may be displayed as a solid line (206) representing the mean fit porosity (200) and the dotted lines (208) representing the porosity uncertainty based, at least in part, on the porosity compaction model parameter probability density functions (322, 332).

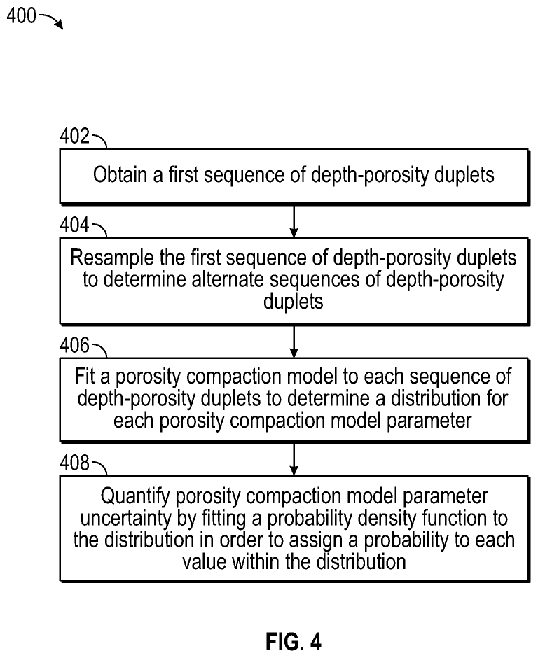

FIG. 4 shows a flowchart (400) that depicts a method to quantify uncertainty in porosity compaction model parameters using probability density functions (322, 332). In step 402, a first sequence of depth-porosity duplets (300) may be obtained from a sedimentary layer using wellbore logs or from rock core samples. A porosity wellbore sequence may typically be determined from a neutron log, a density log, or a sonic log.

In step 404, the first sequence of z-φ(z) duplets (300) is resampled to determine alternate sequences of z-φ(z) duplets (310a, 310b, 310c). Common resampling methods include a bootstrapping method, a jackknifing method, and a Monte Carlo method. To bootstrap a dataset of sample size n may be to randomly resample the dataset n times with no restrictions as to the number of times a sample within the dataset can be selected. Bootstrapping may be easy to implement and robust for obtaining uncertainty in a dataset. To jackknife a dataset of sample size n may be to remove one different sample from the dataset for each new dataset to determine alternate subsets of sample size n-1 Similar to bootstrapping, jackknifing may be easy to implement. A Monte Carlo method, while it may be more difficult to implement compared to bootstrapping and jackknifing, may have the advantage of being useful on simple as well as complex datasets. A Monte Carlo method may include assuming a probability distribution of the dataset and randomly resampling the probability distribution to obtain alternate datasets.

In step 406, a porosity compaction model (304) may be fit to the first sequence of z-φ(z) duplets (300) and each alternate sequence of z-φ(z) duplets (310a, 310b, 310c) individually. Each fitted porosity compaction model (304, 310a, 310b, 310c) determines one value for each porosity compaction model parameter, c and φ₀. For example, if a first sequence of z-φ(z) duplets (300) was resampled 1000 times, the porosity compaction model (200) may be fit 1001 times to determine 1001 compaction coefficient, c, values and 1001 archaic porosities, φ₀ values.

In step 408, a histogram may be determined for each porosity compaction model parameter (320,330) and a probability density function (322, 332) may be fit to each histogram (320,330). In accordance with one or more embodiments, the width or standard deviation, σ, of the probability density function may quantify the uncertainty in the corresponding compaction parameter in that a probability has now been determined for each porosity compaction model parameter value.

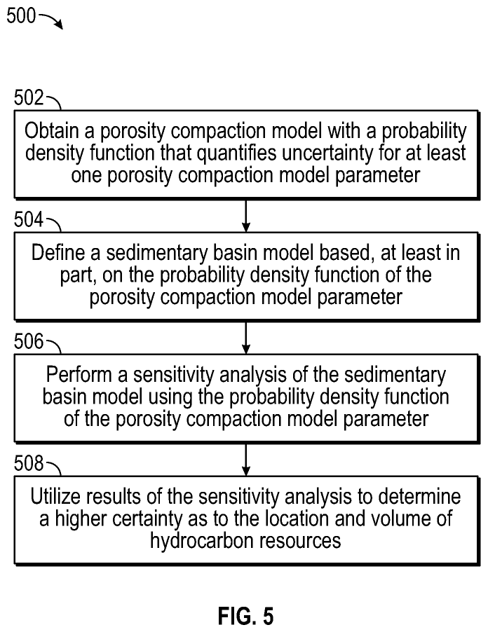

FIG. 5 shows a flowchart for implementing porosity compaction models (200) with probability density functions (322, 332) into sedimentary basin models, in accordance with one or more embodiments. In step 502, probability density functions (322, 332) for at least one porosity compaction model parameter has previously been calculated to quantify porosity compaction model parameter uncertainty following the methodology described in FIG. 4.

In step 504, the porosity compaction model (200) with at least one probability density function (322, 332) may be implemented into a sedimentary basin model. A sedimentary basin model may be a three-dimensional map of the Earth's crust that comprises at least one sedimentary layer coupled with physical properties associated with each sedimentary layer. In some embodiments, there may be a time dimension that exists is the past, present, and/or future. A probability density function (322, 332) for at least one porosity compaction model parameter may be used, at least in part, to model each sedimentary layer in the sedimentary basin model.

In step 506, a sensitivity analysis may be performed on the sedimentary basin model outputs. Different porosity compaction model parameter values and each value's associated probability based on the probability density function (322, 332) may be selected to determine how different porosity compaction model parameter values affect sedimentary basin model outputs. For example, 100 compaction coefficient values, c, and the values' associated probabilities may be input into the sedimentary model to find significant changes in a sedimentary layer thickness map output by the sedimentary basin model.

In step 508, sensitivity analysis results may lead to higher certainty in the sedimentary model outputs. Specifically, sensitivity results may lead to higher certainty in the location and volume of hydrocarbon resources within sedimentary layers.

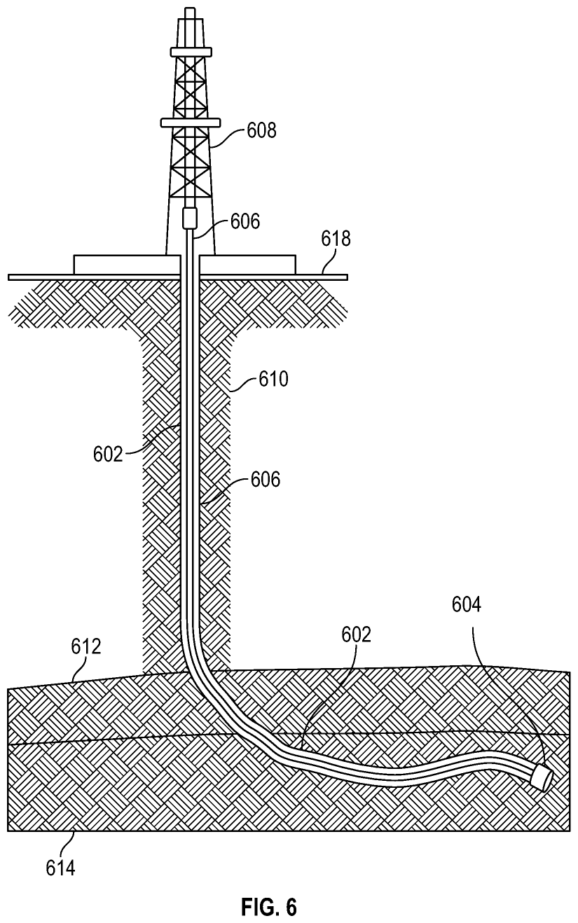

FIG. 6 illustrates a drill system, in accordance with one or more embodiments. A borehole (602) may be drilled using a drill bit (604) attached to a drillstring (606) further attached to a drill rig (608), where the drill rig (608) is located on the Earth's surface (618). The borehole (602) may traverse a plurality of overburden layers (610) and one or more cap-rock layers (612) to reach a hydrocarbon resource (614). Wellbore logs may be collected during drilling using logging-while-drilling tools. Alternatively, rock core samples may be collected during drilling using a core drill bit (604). Depth-porosity duplets (302) may then be estimated from the collected wellbore logs and/or rock core samples. The workflow presented in FIG. 3, FIG. 4, and FIG. 5 may then be implemented to anticipate the location of the hydrocarbon resource (614) currently being drilled or to be drilled in the future using the sedimentary basin model that includes probability density functions (322, 332) for at least one porosity compaction model parameter.

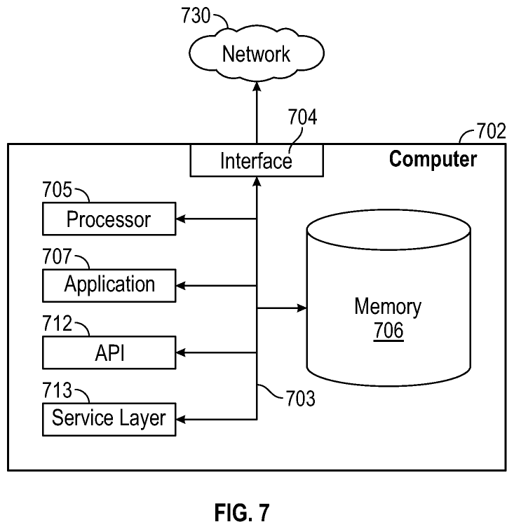

FIG. 7 depicts a block diagram of a computer system (702) used to provide computational functionalities associated with described algorithms, methods, functions, processes, flows, and procedures as described in this disclosure, according to one or more embodiments. The illustrated computer (702) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (702) may include a computer that includes an input device, such as a keypad, keyboard, touch screen, or other device that can accept user information, and an output device that conveys information associated with the operation of the computer (702), including digital data, visual, or audio information (or a combination of information), or a GUI.

The computer (702) can serve in a role as a client, network component, a server, a database or other persistency, or any other component (or a combination of roles) of a computer system for performing the subject matter described in the instant disclosure. The illustrated computer (702) is communicably coupled with a network (730). In some implementations, one or more components of the computer (702) may be configured to operate within environments, including cloud-computing-based, local, global, or other environment (or a combination of environments).

At a high level, the computer (702) is an electronic computing device operable to receive, transmit, process, store, or manage data and information associated with the described subject matter. According to some implementations, the computer (702) may also include or be communicably coupled with an application server, e-mail server, web server, caching server, streaming data server, business intelligence (BI) server, or other server (or a combination of servers).

The computer (702) can receive requests over network (730) from a client application (for example, executing on another computer (702)) and responding to the received requests by processing the said requests in an appropriate software application. In addition, requests may also be sent to the computer (702) from internal users (for example, from a command console or by other appropriate access method), external or third-parties, other automated applications, as well as any other appropriate entities, individuals, systems, or computers.

Each of the components of the computer (702) can communicate using a system bus (703). In some implementations, any or all of the components of the computer (702), both hardware or software (or a combination of hardware and software), may interface with each other or the interface (704) (or a combination of both) over the system bus (703) using an application programming interface (API) (712) or a service layer (713) (or a combination of the API (712) and service layer (713). The API (712) may include specifications for routines, data structures, and object classes. The API (712) may be either computer-language independent or dependent and refer to a complete interface, a single function, or even a set of APIs. The service layer (713) provides software services to the computer (702) or other components (whether or not illustrated) that are communicably coupled to the computer (702). The functionality of the computer (702) may be accessible for all service consumers using this service layer. Software services, such as those provided by the service layer (713), provide reusable, defined business functionalities through a defined interface. For example, the interface may be software written in JAVA, C++, or other suitable language providing data in extensible markup language (XML) format or another suitable format. While illustrated as an integrated component of the computer (702), alternative implementations may illustrate the API (712) or the service layer (713) as stand-alone components in relation to other components of the computer (702) or other components (whether or not illustrated) that are communicably coupled to the computer (702). Moreover, any or all parts of the API (712) or the service layer (713) may be implemented as child or sub-modules of another software module, enterprise application, or hardware module without departing from the scope of this disclosure.

The computer (702) includes an interface (704). Although illustrated as a single interface (704) in FIG. 7, two or more interfaces (704) may be used according to particular needs, desires, or particular implementations of the computer (702). The interface (704) is used by the computer (702) for communicating with other systems in a distributed environment that are connected to the network (730). Generally, the interface (704) includes logic encoded in software or hardware (or a combination of software and hardware) and operable to communicate with the network (730). More specifically, the interface (704) may include software supporting one or more communication protocols associated with communications such that the network (730) or interface's hardware is operable to communicate physical signals within and outside of the illustrated computer (702).

The computer (702) includes at least one computer processor (705). Although illustrated as a single computer processor (705) in FIG. 7, two or more processors may be used according to particular needs, desires, or particular implementations of the computer (702). Generally, the computer processor (705) executes instructions and manipulates data to perform the operations of the computer (702) and any algorithms, methods, functions, processes, flows, and procedures as described in the instant disclosure.

The computer (702) also includes a memory (706) that holds data for the computer (702) or other components (or a combination of both) that can be connected to the network (730). For example, memory (706) can be a database storing data consistent with this disclosure. Although illustrated as a single memory (706) in FIG. 7, two or more memories may be used according to particular needs, desires, or particular implementations of the computer (702) and the described functionality. While memory (706) is illustrated as an integral component of the computer (702), in alternative implementations, memory (706) can be external to the computer (702).

The application (707) is an algorithmic software engine providing functionality according to particular needs, desires, or particular implementations of the computer (702), particularly with respect to functionality described in this disclosure. For example, application (707) can serve as one or more components, modules, applications, etc. Further, although illustrated as a single application (707), the application (707) may be implemented as multiple applications (707) on the computer (702). In addition, although illustrated as integral to the computer (702), in alternative implementations, the application (707) can be external to the computer (702).

There may be any number of computers (702) associated with, or external to, a computer system containing a computer (702), wherein each computer (702) communicates over network (730). Further, the term “client,” “user,” and other appropriate terminology may be used interchangeably as appropriate without departing from the scope of this disclosure. Moreover, this disclosure contemplates that many users may use one computer (702), or that one user may use multiple computers (702).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, any means-plus-function clauses are intended to cover the structures described herein as performing the recited function(s) and equivalents of those structures. Similarly, any step-plus-function clauses in the claims are intended to cover the acts described here as performing the recited function(s) and equivalents of those acts. It is the express intention of the applicant not to invoke 35 U.S.C. § 112(f) for any limitations of any of the claims herein, except for those in which the claim expressly uses the words “means for” or “step for” together with an associated function.

What is claimed is:

1. A method of quantifying an uncertainty in at least one porosity compaction model parameter, comprising:
obtaining a first sequence of depth-porosity duplets from a sedimentary layer;
generating a plurality of alternate sequences of depth-porosity duplets based, at least in part, on resampling the first sequence;
estimating a plurality of values for the porosity compaction model parameter based on fitting a porosity compaction model to the first sequence and each alternate sequence; and
quantifying the uncertainty in the porosity compaction model parameter based on determining the value of a parameter of probability density function fit to a histogram of the plurality of values for the porosity compaction model parameter.

2. The method of claim 1, further comprising:
defining a sedimentary basin model based, at least in part, on the uncertainty in the porosity compaction model parameter; and
determining a probability of a location a volume of a hydrocarbon resource based, at least in part, on the sedimentary basin model.

3. The method of claim 1, wherein measuring the first sequence of depth-porosity duplets comprises using at least one of: a wellbore log and a rock core sample.

4. The method of claim 1, wherein resampling the first sequence of depth-porosity duplets comprises using at least one of: a bootstrapping method; a jackknifing method; and a Monte Carlo method.

5. The method of claim 1, wherein the porosity compaction model parameter comprises an archaic porosity parameter and a compaction coefficient.

6. The method of claim 1, wherein the probability density function comprises at least one of: a uniform distribution; a normal distribution; a skew distribution; an exponential distribution; a power-law distribution; and a binomial distribution.

7. The method of claim 1, wherein the histogram displays a frequency for each value within the plurality of values.

8. A non-transitory computer readable medium storing instructions executable by a computer processor, the instructions comprising functionality for:
receiving a first sequence of depth-porosity duplets from a sedimentary layer;
generating a plurality of alternate sequences of depth-porosity duplets based, at least in part, on resampling the first sequence;
estimating a plurality of values for a porosity compaction model parameter based on fitting a porosity compaction model to the first sequence and each alternate sequence; and
quantifying an uncertainty in the porosity compaction model parameter based on determining the value of a parameter of probability density function fit to a histogram of the plurality of values for the porosity compaction model parameter.

9. The non-transitory computer readable medium of claim 8, further comprising:
receiving a sedimentary basin model based, at least in part, on the uncertainty in the porosity compaction model parameter; and
determining a probability of a location a volume of a hydrocarbon resource based, at least in part, on the sedimentary basin model.

10. The non-transitory computer readable medium of claim 8, wherein measuring the first sequence of depth-porosity duplets comprises using at least one of: a wellbore log and a rock core sample.

11. The non-transitory computer readable medium of claim 8, wherein resampling the first sequence of depth-porosity duplets comprises using at least one of: a bootstrapping method; a jackknifing method; and a Monte Carlo method.

12. The non-transitory computer readable medium of claim 8, wherein the porosity compaction model parameter comprises an archaic porosity parameter and a compaction coefficient.

13. The non-transitory computer readable medium of claim 8, wherein the probability density function comprises at least one of: a uniform distribution; a normal distribution; a skew distribution; an exponential distribution; a power-law distribution; and a binomial distribution.

14. The non-transitory computer readable medium of claim 8, wherein the histogram displays a frequency for each value within the plurality of values.

15. A system, comprising:
a well tool configured to sample porosity at a plurality of depths; and
a computer system configured to:
receive a first sequence of depth-porosity duplets from a sedimentary layer collected using the well tool;
generate a plurality of alternate sequences of depth-porosity duplets based, at least in part, on resampling the first sequence;
estimate a plurality of values for a porosity compaction model parameter based on fitting a porosity compaction model to each sequence; and
quantify an uncertainty in the porosity compaction model parameter based on determining the value of a parameter of probability density function fit to a histogram of the plurality of values for the porosity compaction model parameter.

16. The system of claim 15, further comprising:
a computer system configured to:
receive a sedimentary basin model based, at least in part, on the uncertainty in the porosity compaction model parameter; and
determine a probability of a location and a volume of a hydrocarbon resource based, at least in part, on the sedimentary basin model.

17. The system of claim 15, wherein measuring the first sequence of depth-porosity duplets comprises using at least one of: a wellbore log and a rock core sample.

18. The system of claim 15, wherein resampling the first sequence of depth-porosity duplets comprises using at least one of: a bootstrapping method; a jackknifing method; and a Monte Carlo method.

19. The system of claim 15, wherein the porosity compaction model parameter comprises an archaic porosity parameter and a compaction coefficient.

20. The system of claim 15, wherein the probability density function comprises at least one of: a uniform distribution; a normal distribution; a skew distribution; an exponential distribution; a power-law distribution; and a binomial distribution.
